(19) United States
(12) Patent Application Publication
(10) Pub. No.: US 2002/0109548 A1
(43) Pub. Date: Aug. 15, 2002

(54) Power amplifying circuit

(75) Inventor: Akio Hosokawa, Tokyo (JP)

Correspondence Address: SUGHRUE MION, PLLC, 2100 PENNSYLVANIA AVENUE, N.W., WASHINGTON, DC, 20037, US

(73) Assignee: NEC CORPORATION

(21) Appl. No.: 10/066,722

(22) Filed: Feb. 6, 2002

(30) Foreign Application Priority Data
Feb. 9, 2001 (JP) 33927/2001

(51) Int. Cl. H03F 3/26; H03F 3/18

(52) U.S. Cl. 330/264

(57) ABSTRACT

A power amplifying circuit according to the invention is provided with a first predriver that amplifies input voltage and outputs first driving voltage and second driving voltage lower than the first driving voltage, a second predriver that amplifies the input voltage and outputs third driving voltage and fourth driving voltage higher than the third driving voltage, a first push-pull output circuit including a first PMOS transistor and a first NMOS transistor to the respective gates of which the first driving voltage and the third driving voltage are respectively input, a second push-pull output circuit including a second PMOS transistor and a second NMOS transistor to the respective gates of which the second driving voltage and the fourth driving voltage are respectively input and a common output terminal connected to the output terminal of the first push-pull output circuit and the output terminal of the second push-pull output circuit in common.

### BACKGROUND OF THE INVENTION

1. Field of the Invention

The present invention relates to a power amplifying circuit, particularly relates to a power amplifying circuit wherein short-circuit current is prevented from being caused in operation and crossover distortion is reduced.

2. Description of the Prior Art

Recently, a power amplifying circuit formed by a MOS transistor is mounted in various devices and is also used for a driver of a voice coil motor (VCM) for driving a head that reads and writes data from/to a hard disk. The power amplifying circuit used for a VCM driver of a hard disk is demanded so that the power consumption is reduced corresponding to a demand for the consumed current of a notebook-sized personal computer and others and the distortion is possibly reduced to precisely control the position of a head for reading a signal recorded on the hard disk.

A conventional type power amplifying circuit that meets the two demands for the reduction of power consumption and the reduction of distortion is disclosed in Japanese published unexamined patent application No. Hei 8-293740 and referring to FIGS. 5 to 7, the power amplifying circuit disclosed in this patent application will be described below.

FIG. 5 is a circuit diagram showing the power amplifying circuit disclosed in the patent application and the power amplifying circuit is composed of an operational amplifier 8, current mirror circuits 6 and 7, predrivers 10 and 11 and a push-pull output circuit 9. The operation of the power amplifying circuit shown in FIG. 5 will be described below.

When the electric potential V− of an inverting input terminal 4 of the operational amplifier 8 is fixed and the electric potential V+ of a non-inverting input terminal 3 is turned higher than the electric potential V− of the inverting input terminal 4, a high-level signal is output from the operational amplifier 8. The high-level signal is output to a common input terminal of the predriver 10 and the predriver 11, hereby, the predriver 10 outputs a low-level signal and turns on a PMOS transistor QP3 forming the push-pull output circuit 9.

In the meantime, the predriver 11 outputs a low-level signal when the a high-level signal is input from the operational amplifier 8 and turns off an NMOS transistor QN3 forming the push-pull output circuit 9. As a result, the output voltage Vout of an output terminal 5 of the power amplifying circuit becomes a high level. When the electric potential V+ of the non-inverting input terminal 3 of the operational amplifier 8 is turned lower than the electric potential V− of the inverting input terminal 4, Vout of the output terminal 5 of the power amplifying circuit becomes a low level by the operation reverse to the above-mentioned operation.

Next, referring to FIG. 6 in which circuit constants and the bias voltage of each bias point are described in the same circuit diagram as that shown in FIG. 5, the operation in case the respective electric potential V+ and V− of the non-inverting input terminal 3 and the inverting input terminal 4 of the operational amplifier 8 are equal will be described. To simplify the description, power supply voltage VDD shall be 5 V and the threshold voltage Vt of each transistor shall be 1 V.

When the respective electric potential V+ and V− of the non-inverting input terminal 3 and the inverting input terminal 4 of the operational amplifier 8 are equal, the operational amplifier 8 outputs electric potential equivalent to a half of the power supply voltage Vd (=5 V), that is, 2.5 V. At this time, 1 V and 1.5 V are respectively applied to a PMOS transistor QP1 forming the current mirror circuit 6 and a resistor R1 forming the predriver 10.

As the PMOS transistors QP1 and QP2 form the current mirror circuit, current of the same magnitude flows in the resistor R1 and a resistor R2 when the PMOS transistors are equal in size. Then, when the ratio R1 to R2 in a resistance value of the resistor R1 to the resistor R2 is set to 15 kΩ to 40 kΩ, that is, 1.5 to 4, 4 V is applied to the resistor R2. One volt is applied between the source and the gate of the PMOS transistor QP3 forming the push-pull output circuit 9 and the PMOS transistor QP3 just starts to be turned on.

In the meantime, 1 V and 1.5 V are respectively applied to an NMOS transistor QN1 forming the current mirror circuit 7 and a resistor R11 forming the predriver 11. As the NMOS transistors QN1 and QN2 form the current mirror circuit, current of the same magnitude flows in the resistor R11 and the resistor R12 when the transistors are equal in size.

Then, in case the ratio R11 to R12 in a resistance value of the resistor R11 to the resistor R12 is set to 15 kΩ to 40 kΩ, that is, 1.5 to 4, 4V is applied to the resistor R12. Also, 1 V is applied between the source and the gate of the NMOS transistor QN3 forming the push-pull output circuit 9 and the transistor QN3 just starts to be turned on. As both the PMOS transistor QP3 and the NMOS transistor QN3 are not completely turned on yet, no short-circuit current flows. At this time, the output voltage Vout of the output terminal 5 of the power amplifying circuit is equivalent to electric potential Vd/2 equivalent to a half of the power supply voltage Vd.

As described above, as in the conventional type power amplifying circuit, either of the PMOS transistor QP3 or the NMOS transistor QN3 is turned off even if the output voltage is at a high level, at an intermediate level and at a low level, the conventional type power amplifying circuit forms a class B power amplifying circuit in which no short-circuit current flows from a power terminal 1 to a ground (GND) terminal 2.

However, in the above-mentioned conventional type power amplifying circuit, another problem that when input voltage is rapidly switched, short-circuit current flows and when a circuit constant is set so that no short-circuit current flows, the crossover distortion of output current increases is caused. Next, referring to the circuit diagram shown in FIG. 5 and FIG. 7 showing signal waveforms, a mechanism of the occurrence of short-circuit current will be described.

FIG. 7 show the hourly variation of output voltage Vout, the gate voltage Vg (QP3) of the PMOS transistor QP3 and the gate voltage Vg (QN3) of the NMOS transistor QN3 in case each threshold value and each resistance value of the MOS transistors and the resistors respectively forming the power amplifying circuit shown in FIG. 5 are design center values. Input voltage V− applied to the inverting input terminal 4 shall be fixed and input voltage V+ applied to the non-inverting input terminal 3 shall linearly increase from 0 V to the power supply voltage Vd.

The output voltage of the operational amplifier 8 is input to the predriver 10 and the predriver 11, the output of the current mirror circuit 6 is converted to voltage by the resistor R2 and the voltage drives the gate of the PMOS transistor QP3 forming the push-pull output circuit 9. The output of the current mirror circuit 7 is converted to voltage by the resistor R12 and the voltage drives the gate of the NMOS transistor QN3 forming the push-pull output circuit 9.

When the output voltage of the operational amplifier 8 linearly increases from a low level to a high level, the gate voltage Vg (QN3) of the NMOS transistor QN3 forming the push-pull output circuit 9 decreases from a VDD level to a GND level as shown in FIG. 7A.

In the meantime, the gate voltage Vg (QP3) of the PMOS transistor QP3 of the push-pull output circuit 9 also afterward decreases from a VDD level to a GND level. To explain concretely, as the gate voltage Vg (QP3) of the PMOS transistor QP3 of the push-pull output circuit 9 reaches the threshold Vtp of the PMOS transistor QP3 at the same time as the gate voltage Vg (QN3) of the NMOS transistor QN3 forming the push-pull output circuit 9 reaches the threshold Vtn of the NMOS transistor QN3, the output voltage Vout of the power amplifying circuit linearly increases from a low level to a high level. At this time, as shown in FIG. 7B, no short-circuit current flows in the push-pull output circuit.

That is, to pay attention to the gate voltage Vg (QN3) of the NMOS transistor QN3, as the gate voltage Vg (QN3) is higher than the threshold Vtn between time t1 and time t2 (shown by a thick line), the NMOS transistor QN3 is kept on and as the gate voltage Vg (QN3) is lower than the threshold Vtn between the time t2 and time t3, the NMOS transistor QN3 is turned off.

In the meantime, to pay attention to the gate voltage Vg (QP3) of the PMOS transistor QP3, as the gate voltage Vg (QP3) is higher than the threshold Vtp between the time t1 and the time t2 (shown by a thick line), the PMOS transistor QP3 is kept off and as the gate voltage Vg (QP3) is lower than the threshold Vtp between the time t2 and the time t3, the PMOS transistor QP3 is turned on.

Therefore, as the ON state/the OFF state of the PMOS transistor QP3 and the NMOS transistor QN3 is switched at the time t2 and the PMOS transistor and the NMOS transistor are not simultaneously turned on, no short-circuit current flows.

However, actually, as each threshold and each resistance value of the MOS transistors and the resistors respectively forming the power amplifying circuit disperse from their design center values, short-circuit current is caused.

Next, referring to FIG. 8 showing signal waveforms, the operation of the power amplifying circuit in case there is dispersion among circuit elements forming the power amplifying circuit will be described.

FIG. 8 show signal waveforms showing the operation of the power amplifying circuit in case the threshold Vtp′ of the PMOS transistor QP3 is smaller than the threshold Vtp shown in FIG. 7. The NMOS transistor QN3 is kept on between time t1 and time t2 as shown in FIG. 7 and is turned off between the time t2 and time t3. In the meantime, as the threshold Vtp′ of the PMOS transistor QP3 is smaller than the threshold Vtp, the PMOS transistor QP3 is turned off between the time t1 and time t2′ earlier than the time t2 and is kept on between the time t2′ and the time t3.

Therefore, as the PMOS transistor QP3 and the NMOS transistor QN3 are simultaneously turned on between the time t2′ and the time t2 as shown by a thick line, large short-circuit current shown in FIG. 8B flows.

For a measure for the above-mentioned short-circuit current, it is considered that the resistance values of the resistor R2 and the resistor R12 are set to large values so that the PMOS transistor QP3 and the NMOS transistor QN3 respectively forming the push-pull output circuit 9 are not simultaneously turned on. FIG. 9 show signal forms at this time.

In case design is made in consideration of manufacturing dispersion, a range of power supply voltage and a range of temperature so that no short-circuit current is caused, the PMOS transistor QP3 and the NMOS transistor QN3 respectively forming the push-pull output circuit 9 are simultaneously turned off between time t21 and time t22 before and after time t2 corresponding to the central condition of the dispersion.

As a result, as the output voltage Vout of the power amplifying circuit is not linear between the time t21 and the time t22, another problem that the crossover distortion of output current is caused occurs.

### BRIEF SUMMARY OF THE INVENTION

### OBJECT OF THE INVENTION

The object of the invention is to provide a power amplifying circuit in which large short-circuit current is prevented from being caused in a push-pull output circuit when an alternate current signal mainly based upon bias voltage is applied to its input terminal and the crossover distortion of output current can be reduced.

### SUMMARY OF THE INVENTION

The power amplifying circuit according to the invention is provided with a first predriver that amplifies input voltage and outputs first driving voltage and second driving voltage lower than the first driving voltage, a second predriver that amplifies input voltage and outputs third driving voltage and fourth driving voltage higher than the third driving voltage, a first push-pull output circuit including a first PMOS transistor and a first NMOS transistor to respective gates of which the first driving voltage and the third driving voltage are respectively input, a second push-pull output circuit including a second PMOS transistor and a second NMOS transistor to the respective gates of which the second driving voltage and the fourth driving voltage are respectively input and a common output terminal connected to the output terminal of the first push-pull output circuit and the output terminal of the second push-pull output circuit in common.

### BRIEF DESCRIPTION OF THE DRAWINGS

The above-mentioned and other objects, features and advantages of this invention will become more apparent by reference to the following detailed description of the invention taken in conjunction with the accompanying drawings, wherein:

FIG. 1 is a circuit diagram showing a first embodiment of a power amplifying circuit according to the invention;

FIG. 2 is a circuit diagram in which bias voltage and circuit constants when the input voltage of two input terminals 3 and 4 are equal in the power amplifying circuit shown in FIG. 1 are added;

FIG. 3 is a circuit diagram showing a second embodiment of the power amplifying circuit according to the invention;

FIGS. 4A and 4B show signal waveforms showing the operation of the circuit shown in FIG. 1;

FIG. 5 is a circuit diagram showing an example of a conventional type power amplifying circuit;

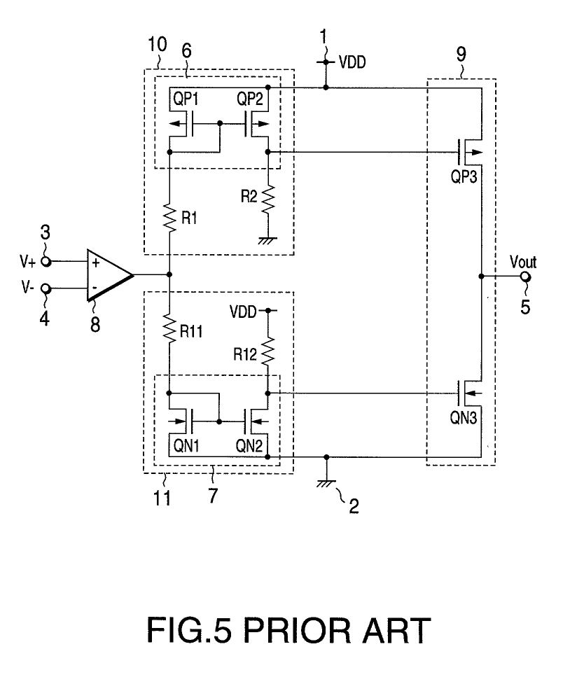

FIG. 6 is a circuit diagram in which bias voltage and circuit constants when the input voltage of two input terminals 3 and 4 are equal in the power amplifying circuit shown in FIG. 5 are added;

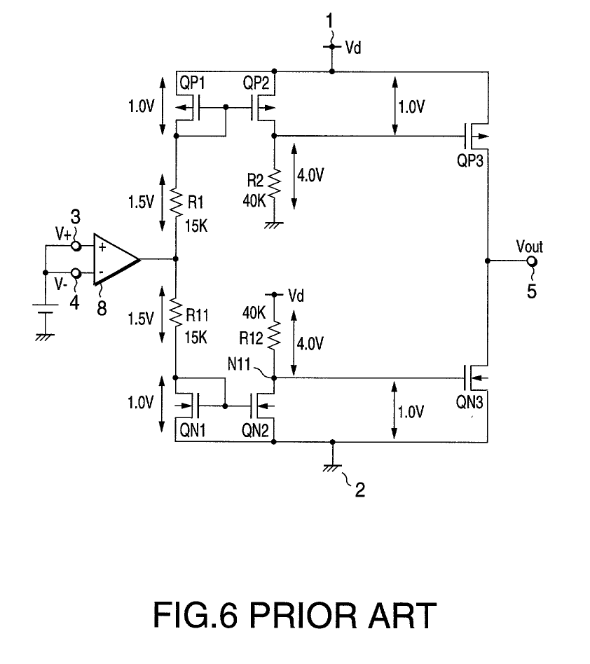

FIGS. 7A and 7B show signal waveforms showing the operation in case the characteristic values of devices forming the power amplifying circuit are design center values of the power amplifying circuit shown in FIG. 5;

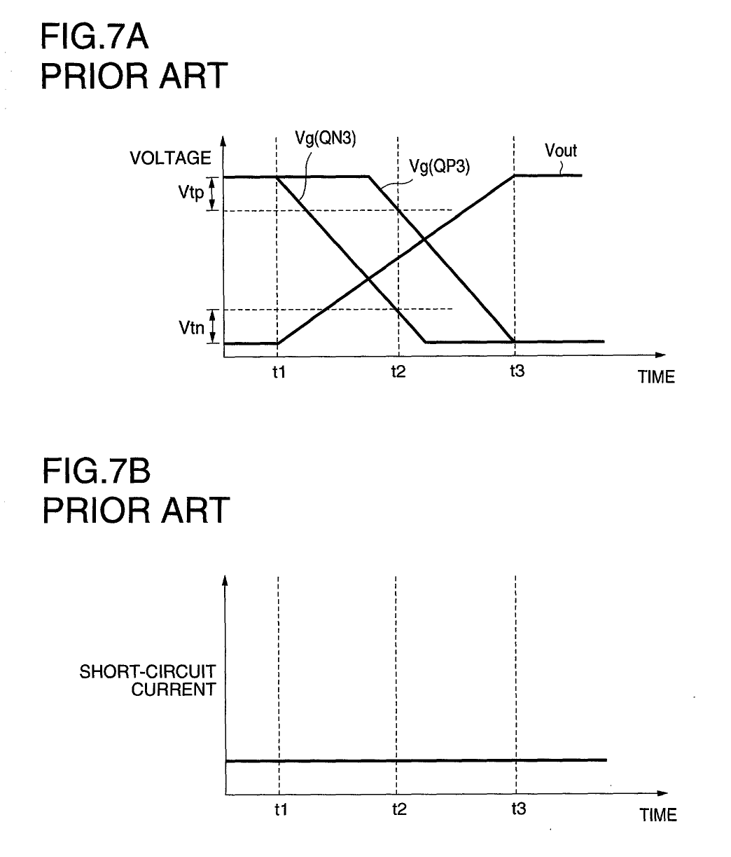

FIGS. 8A and 8B show signal waveforms showing the operation in case the characteristic values of the devices forming the power amplifying circuit are off design center values of the power amplifying circuit shown in FIG. 5; and

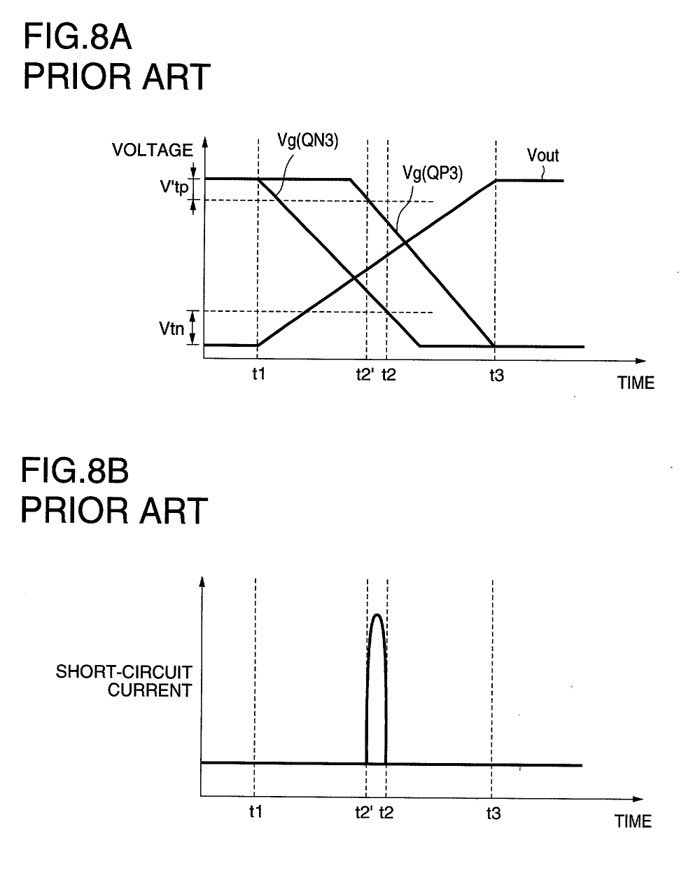

FIGS. 9A and 9B show signal waveforms showing the operation when the power amplifying circuit shown in FIG. 5 is designed so that no short-circuit current is caused.

### DETAILED DESCRIPTION OF THE INVENTION

Next, referring to the drawings, embodiments of a power amplifying circuit according to the invention will be described.

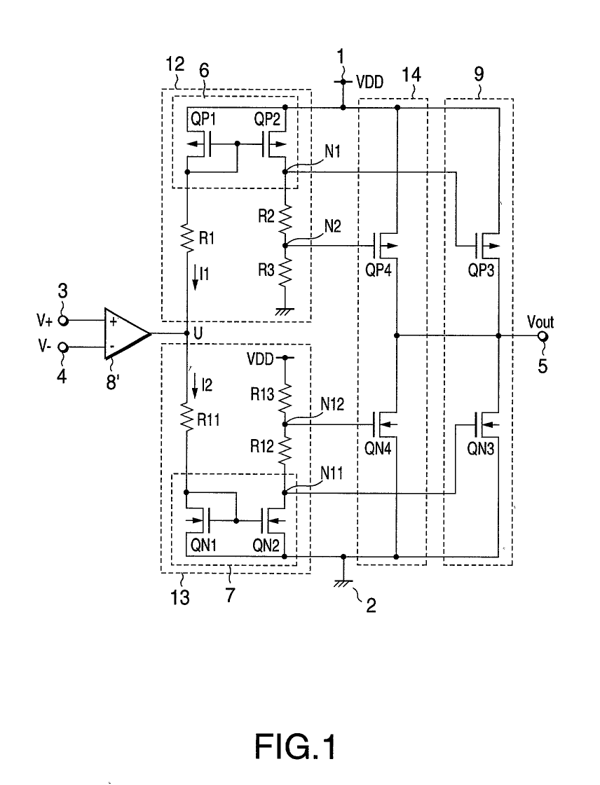

FIG. 1 is a circuit diagram showing a first embodiment of the power amplifying circuit according to the invention and a power amplifying circuit equivalent to the first embodiment includes a differential amplifier 8′ such as an operational amplifier, predrivers 12 and 13 and push-pull output circuits 9 and 14.

The predriver 12 includes a current mirror circuit 6 and resistors R1, R2 and R3, the predriver 13 includes a current mirror circuit 7 and resistors R11, R12 and R13 and further, the current mirror circuit 6 includes a pair of PMOS transistors QP1 and QP2. The current mirror circuit 7 includes a pair of NMOS transistors QN1 and QN2.

The push-pull output circuit 9 is composed of a PMOS transistor QP3 and an NMOS transistor QN3, the push-pull output circuit 14 is composed of a PMOS transistor QP4 and an NMOS transistor QN4, each output terminal of the push-pull output circuits 9 and 14 is connected to an output terminal 5 in common and output voltage Vout is output to the terminal.

The ratio gm (QP3) to gm (QP4) of each mutual conductance of the PMOS transistor QP3 forming the push-pull output circuit 9 and the PMOS transistor QP4 forming the push-pull output circuit 14 is set to n:1 and “n” is set to approximately 10 to 10000 for example so that “n” is large enough, compared with 1. Concretely, the channel length of the PMOS transistors QP3 and QP4 is set to an equal value and the channel width W (QP3) of the PMOS transistor QP3 is set to n times of the channel width W (QP4) of the PMOS transistor QP4.

Similarly, the ratio gm (QN3) to gm (QN4) of the mutual conductance of the NMOS transistor QN3 forming the push-pull output circuit 9 and the NMOS transistor QN4 forming the push-pull output circuit 14 is set to n:1 and “n” is set to approximately 10 to 10000 for example so that “n” is large enough, compared with 1. Concretely, the channel length of the NMOS transistors QN3 and QN4 is set to an equal value and the channel width W (QN3) of the NMOS transistor QN3 is set to n times of the channel width W (QN4) of the NMOS transistor QN4.

The differential amplifier 8′ is provided with a non-inverting input terminal 3 to which input voltage V+ is applied and an inverting input terminal 4 to which input voltage V− is applied and applies output voltage U to each input terminal of the predrivers 12 and 13. A first output point N1 of the predriver 12 is connected to the gate of the PMOS transistor QP3 forming the push-pull output circuit 9 and a second output point N2 of the predriver 12 is connected to the gate of the PMOS transistor QP4 forming the push-pull output circuit 14.

Similarly, a first output point N11 of the predriver 13 is connected to the gate of the NMOS transistor QN3 forming the push-pull output circuit 9 and a second output point N12 of the predriver 13 is connected to the gate of the NMOS transistor QN4 forming the push-pull output circuit 14.

Next, the operation of the power amplifying circuit equivalent to the first embodiment of the invention will be described.

When the electric potential V− of the inverting input terminal 4 of the differential amplifier 8′ is fixed and the electric potential V+ of the non-inverting input terminal 3 is turned higher than the electric potential of the inverting input terminal 4, a high-level signal is output. The high-level signal is applied to the common input terminal of the predrivers 12 and 13.

Therefore, as current that flows in the resistor R1 decreases, current that respectively flows in the PMOS transistors QP1 and QP2 also decreases, and the first and second output points N1 and N2 of the predriver 12 are turned at a low level. Hereby, the PMOS transistors QP3 and QP4 of the push-pull output circuits 9 and 14 are turned on.

At this time, as current that flows in the resistor R11 forming the predriver 13 increases reversely to the above description, current that respectively flows in the NMOS transistors QN1 and QN2 also increases, and the first and second output points N11 and N12 of the predriver 13 are turned at a low level. Hereby, the NMOS transistors QN3 and QN4 of the push-pull output circuits 9 and 14 are turned off.

As the PMOS transistors QP3 and QP4 are turned on and the NMOS transistors QN3 and QN4 are turned off as described above, the output voltage Vout of the output terminal 5 of the power amplifying circuit is turned at a high level. When the electric potential of the non-inverting input terminal 3 of the differential amplifier 81 is turned lower than the electric potential of the inverting input terminal 4, the output voltage Vout of the output terminal 5 of the power amplifying circuit is turned at a low level by the operation reverse to the above description.

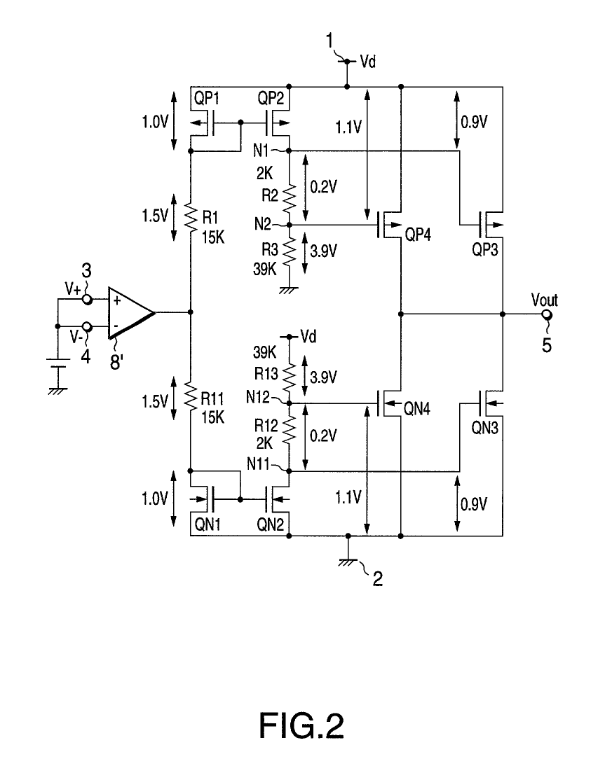

Next, referring to FIG. 2 in which circuit constants and bias voltage at each bias point are described in the same circuit diagram as that shown in FIG. 1, the operation in case each electric potential V+ and V− of the non-inverting input terminal 3 and the inverting input terminal 4 of the differential amplifier 8′ are equal will be described. To simplify the description, power supply voltage Vd shall be 5 V and the threshold Vt of each MOS transistor shall be 1 V.

When each electric potential V+ and V− of the non-inverting input terminal 3 and the inverting input terminal 4 of the differential amplifier 8 are equal, the differential amplifier 8′ outputs electric potential equivalent to a half of the power supply voltage Vd (=5 V), that is, 2.5 V. At this time, 1 V and 1.5 V are respectively applied to the PMOS transistor QP1 and the resistor R1 respectively forming the predriver 12. As the PMOS transistors QP1 and QP2 form a current mirror circuit, current of the same magnitude flows in the resistors R1, R2 and R3 when the PMOS transistors are equal in size, that is, in channel length and channel width.

Then, when the ratio of each resistance value of the resistors R1, R2 and R3 is set to 15 kΩ to 2 kΩ to 39 kΩ, that is, 1.5 to 0.2 to 3.9, 0.2 V and 3.9 V are respectively applied to the resistors R2 and R3. As 0.9 V is applied between the source and the gate of the PMOS transistor QP3 forming the push-pull output circuit 9 and the threshold of the PMOS transistor QP3 is 1 V, the PMOS transistor QP3 is turned off.

In the meantime, as 1.1 V is applied between the source and the gate of the PMOS transistor QP4 forming the push-pull output circuit 14 and the threshold of the PMOS transistor QP4 is 1 V, the PMOS transistor QP4 is turned on.

Similarly, 1 V and 1.5 V are respectively applied to the NMOS transistor QN1 and the resistor R1 respectively forming the predriver 13. As the NMOS transistors QN1 and QN2 form a current mirror circuit, current of the same magnitude flows in the resistors R11, R12 and R13 when the NMOS transistors are equal in size, that is, in channel length and channel width.

Then, when the ratio of each resistance value of the resistors R11, R12 and R13 is set to 15 kΩ to 2 kΩ to 39 kΩ, that is, 1.5 to 0.2 to 3.9, 0.2 V and 3.9 V are respectively applied to the resistors R12 and R13. As 0.9V is applied between the source and the gate of the NMOS transistor QN3 forming the push-pull output circuit 9 and the threshold of the NMOS transistor QN3 is 1 V, the NMOS transistor QN3 is turned off.

In the meantime, as 1.1 V is applied between the source and the gate of the NMOS transistor QN4 forming the push-pull output circuit 14 and the threshold of the NMOS transistor QN4 is 1 V, the NMOS transistor QN4 is turned on as the PMOS transistor QP4.

As the PMOS transistor QP3 and the NMOS transistor QN3 are turned off and the PMOS transistor QP4 and the NMOS transistor QN4 are turned on as described above, the output voltage Vout of the output terminal 5 of the power amplifying circuit becomes a low-impedance state and an intermediate voltage level (Vd/2) Next, the operation of the power amplifying circuit according to the invention in case input voltage V− is fixed and input voltage V+ is varied will be described.

When input voltage V+ is varied from 0 V to the power supply voltage Vd, the output voltage U of the differential amplifier 8′ similarly varies from Vt to power supply voltage (Vd−Vt) When the threshold of the PMOS transistor is Vtp, the threshold of the NMOS transistor is Vtn and current that flows in the resistors R1 and R11 is respectively I1 and I2, the current I1 and I2 are calculated according to the following expressions (1) and (2).

I1=(Vd−Vtp−U)/R1 (1)

I2=(U−Vtp)/R11 (2)

As current that flows in the resistors R2 and R3 is equal to the current I1, voltage V1 and V2 at nodes N1 and N2 are calculated according to the following expressions (3) and (4).

V1=(R2+R3)·I1=(Vd−Vtp−U)·(R2+R3)/R1 (3)

V2=R3·I1=(Vd−Vtp−U)·R3/R1 (4)

When V1 shall be acquired according to {Vd−(Vtp−α)}(α: dispersion margin) and (Vd−V2) is calculated according to the expression (4) to acquire a condition that the PMOS transistor QP3 is turned off and the PMOS transistor QP4 is turned on, the following expression (5) is acquired.

Vd−V2=Vd−(R3/(R2+R3))·(Vd−Vtp+α) (5)

When Vd−V2≧Vtp+α, the following expression (6) is acquired.

(R2·Vd+R3·(Vtp−α))/(R2+R3)≧Vtp+α (6)

That is, to turn off the PMOS transistor QP3 and to turn on the PMOS transistor QP4, the values of the resistors R2 and R3 have only to be determined so that the expression (6) is met.

Similarly, voltage V11 and V12 at the nodes N11 and N12 are respectively calculated according to the following expressions (7) and (8).

V11=Vd−(U−Vtn)·R13/R11 (7)

V12=Vd−(U−Vtn)·(R12+R13)/R11 (8)

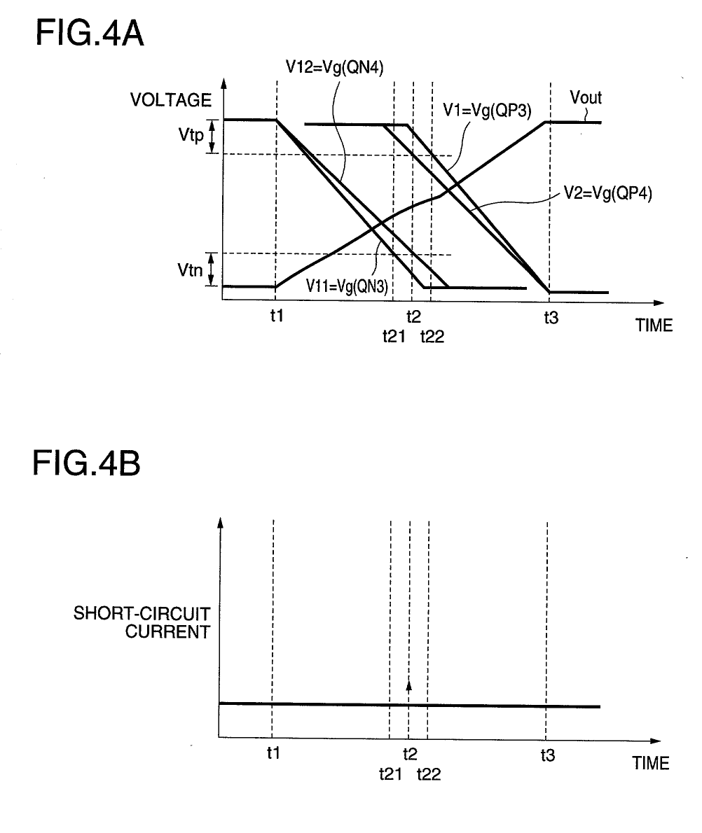

FIG. 4 show the voltage V1, V2, V11 and V12, that is, each voltage of the gate voltage Vg (QP3) of the PMOS transistor QP3, the gate voltage Vg (QP4) of the PMOS transistor QP4, the gate voltage Vg (QN3) of the NMOS transistor QN3 and the gate voltage Vg (QN4) of the NMOS transistor QN4 and output voltage Vout when input voltage V+ linearly increases as time goes, referring to the expressions (3), (4), (7) and (8).

As known from FIG. 4, the gate voltage Vg (QN3) and Vg (QN4) both decrease from time t1, the gate voltage Vg (QN3) reaches the threshold Vtn earlier at time t2 and the NMOS transistor QN3 is turned off. The gate voltage Vg (QN4) reaches the threshold Vtn at the time t2 and the NMOS transistor QN4 is turned off.

As known from this, the NMOS transistors QN3 and QN4 are both turned off between the time t1 and time t21, the NMOS transistor QN3 is kept off and the NMOS transistor QN4 is turned on respectively between the time 21 and the time t2.

In the meantime, the PMOS transistor QP4 is turned on between the time t2 and time t22, the PMOS transistor QP3 is turned off and the PMOS transistors QP3 and QP4 are both turned on between the time t22 and time t3.

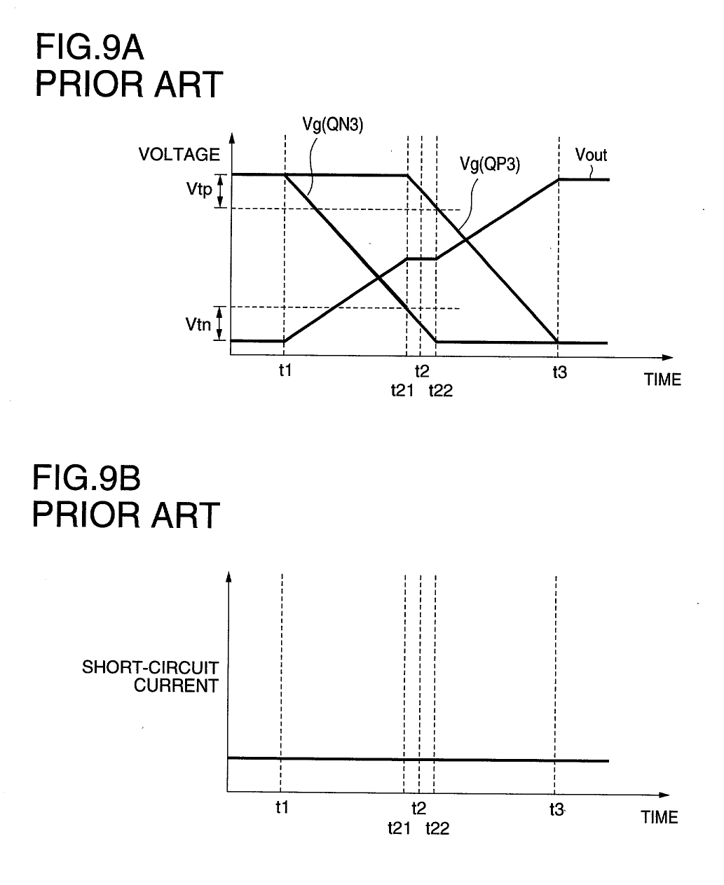

Therefore, as at least either of the PMOS transistor QP4 or the NMOS transistor QN4 is turned on between the time t21 and the time t22, the problem that both the PMOS transistor QP3 and the NMOS transistor QN3 are turned off, output resistance increases and crossover distortion is caused as shown in FIG. 9 is solved. That is, the output voltage Vout shown in FIG. 4 varies, also keeping the inclination of low resistance near intermediate voltage (Vd/2) differently from the output voltage Vout shown in FIG. 9.

As known from the above description, as at least either of the PMOS transistor QP4 or the NMOS transistor QN4 is turned on in the power amplifying circuit according to the invention even if the values of the devices forming the power amplifying circuit disperse, output resistance is low in the whole range of output voltage and no crossover distortion is caused.

The power amplifying circuit according to the invention is characterized in that as each size of the PMOS transistor QP4 and the NMOS transistor QN4 is small, short-circuit current caused in the vicinity of the time t2 is small as shown in FIG. 4B and the power consumption of the power amplifying circuit according to the invention in case output voltage Vout varies from a high level to a low level or from a low level to a high level is greatly small, compared with the power consumption of the conventional type power amplifying circuit.

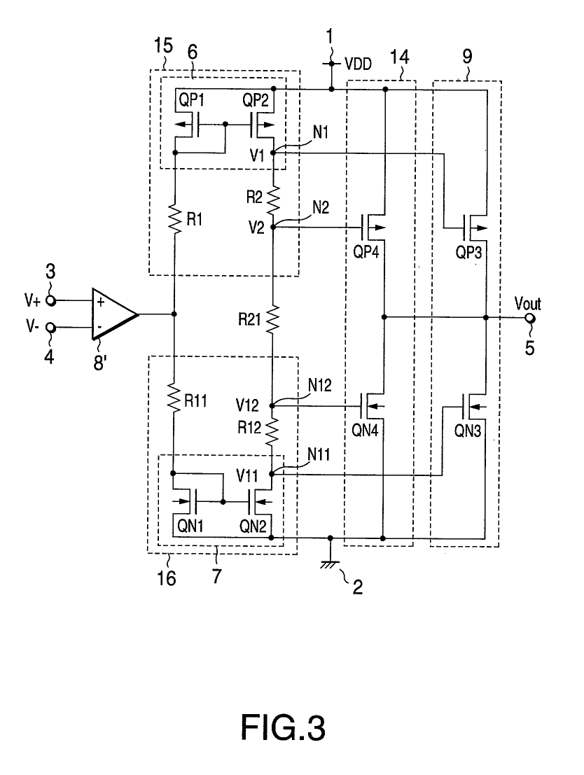

Next, referring to FIG. 3, a second embodiment of the power amplifying circuit according to the invention will be described.

A power amplifying circuit shown in FIG. 3 is different in that the predrivers 12 and 13 respectively forming the power amplifying circuit shown in FIG. 1 are predrivers 15 and 16, one end of a resistor R2 is connected to the gate of a PMOS transistor QP4 and is connected to the gate of an NMOS transistor QN4 and a resistor R12 via a resistor R21, however, the other circuit configuration is similar to that shown in FIG. 1. The detailed description of the circuit operation is omitted, however, the similar operation as the operation of the circuit shown in FIG. 1 is made. The power amplifying circuit equivalent to this embodiment is characterized in that the power consumption is further smaller, compared with that of the power amplifying circuit shown in FIG. 1.

That is, the reason is that in the power amplifying circuit shown in FIG. 1, current flows on two paths of one path, a power source→a PMOS transistor QP2→the resistor R2→a resistor R3→GND and one path, the power source→a resistor R13→the resistor R12→an NMOS transistor QN2→GND, however, in the power amplifying circuit shown in FIG. 3, current flows on one path as the power source→the PMOS transistor QP2→the resistor R2→the resistor R21→the resistor R12→the NMOS transistor QN2→GND. The power amplifying circuit equivalent to the second embodiment has an advantage that the number of the resistors is reduced by one and the resistance value can be reduced.

As described above, the power amplifying circuit according to the invention is characterized in that as output resistance is always low even if output current becomes a zero level, no crossover distortion is caused.

Also, the power amplifying circuit according to the invention has effect that short-circuit current can be reduced.

Although the invention has been described with reference to specific embodiments, this description is not meant to be construed in a limiting sense. Various modifications of the disclosed embodiments will become apparent to persons skilled in the art upon reference to the description of the invention. It is therefore contemplated that the appended claims will cover any modifications or embodiments as fall within the true scope of the invention.

What is claimed is:

1. A power amplifying circuit, comprising:
a first predriver that amplifies input voltage and outputs first driving voltage and second driving voltage lower than the first driving voltage;
a second predriver that amplifies the input voltage and outputs third driving voltage and fourth driving voltage higher than the third driving voltage;
a first push-pull output circuit including a first PMOS transistor and a first NMOS transistor to the respective gates of which the first driving voltage and the third driving voltage are respectively input;
a second push-pull output circuit including a second PMOS transistor and a second NMOS transistor to the respective gates of which the second driving voltage and the fourth driving voltage are respectively input; and
a common output terminal connected to the output terminal of the first push-pull output circuit and the output terminal of the second push-pull output circuit in common.

2. A power amplifying circuit according to claim 1, wherein:
the mutual conductance of the first PMOS transistor is larger by m (m: constant) times than the mutual conductance of the second PMOS transistor; and
the mutual conductance of the first NMOS transistor is larger by n (n: constant) times than the mutual conductance of the second NMOS transistor.

3. A power amplifying circuit according to claim 1, wherein:
before the first PMOS transistor is switched from an OFF state to an ON state by the first driving voltage, the second PMOS transistor is kept on by the second driving voltage; and
after the first NMOS transistor is switched from an ON state to an OFF state by the third driving voltage, the second NMOS transistor is also kept on by the fourth driving voltage.

4. A power amplifying circuit according to claim 1, further comprising:
a differential amplifier that differentially amplifies input signals respectively applied to two input terminals and outputs the input voltage.

5. A power amplifying circuit according to claim 1, wherein:
the first predriver is provided with a first current mirror circuit, a first resistor one end of which is connected to the input terminal of the first current mirror circuit and to the other end of which the input voltage is applied, a second resistor to one end of which the output terminal of the first current mirror circuit is connected and the other end of which is connected the gate of the first PMOS transistor and a third resistor one end of which is connected to the other end of the second resistor and the gate of the second PMOS transistor and the other end of which is connected to a first bias point; and
the second predriver is provided with a second current mirror circuit, a fourth resistor one end of which is connected to the input terminal of the second current mirror circuit and to the other end of which the input voltage is applied, a fifth resistor one end of which is connected to the output terminal of the second current mirror circuit and the other end of which is connected to the gate of the first NMOS transistor and a sixth resistor one end of which is connected to the other end of the fifth resistor and the gate of the second NMOS transistor and the other end of which is connected to a second bias point.

6. A power amplifying circuit, comprising:
a first predriver that amplifies input voltage and outputs first driving voltage and second driving voltage lower than the first driving voltage;
a second predriver that amplifies the input voltage and outputs third driving voltage and fourth driving voltage higher than the third driving voltage;
a first push-pull output circuit including a first PMOS transistor and a first NMOS transistor to the respective gates of which the first driving voltage and the third driving voltage are respectively input;
a second push-pull output circuit including a second PMOS transistor and a second NMOS transistor to the respective gates of which the second driving voltage and the fourth driving voltage are respectively input;
a resistor connected between the gate of the second PMOS transistor and the gate of the second NMOS transistor; and
a common output terminal connected to the output terminal of the first push-pull output circuit and the output terminal of the second push-pull output circuit in common.
